(19) United States
(12) Patent Application Publication
(10) Pub. No.: US 2024/0113622 A1
(43) Pub. Date: Apr. 4, 2024

(54) CONTROLLER CIRCUIT OF STEP-DOWN DC/DC CONVERTER AND IN-VEHICLE POWER SUPPLY SYSTEM

(71) Applicant: ROHM Co., LTD., Kyoto (JP)

(72) Inventors: Nobuyuki Yokoyama, Kyoto (JP); Hayato Asano, Kyoto (JP)

(21) Appl. No.: 18/471,648

(22) Filed: Sep. 21, 2023

(30) Foreign Application Priority Data
Oct. 4, 2022 (JP) 2022-160419

(51) Int. Cl. H02M 3/158; B60R 16/03; H02M 1/08; H03F 3/45

(52) U.S. Cl. CPC H02M 3/158; B60R 16/03; H02M 1/08; H03F 3/45273

(57) ABSTRACT

Provided is a controller circuit of a step-down DC/DC converter, the controller circuit including a ramp voltage generating circuit that generates a periodic ramp voltage, a clamp voltage generating circuit that generates a clamp voltage, an error amplifier that generates an error signal that depends on an error between an electrical state of the step-down DC/DC converter and a target state of the electrical state, a clamp circuit that clamps the error signal by using the clamp voltage, and a pulse width modulation comparator that compares the error signal resulting from the clamping by the clamp circuit with the ramp voltage. The ramp voltage generating circuit includes a first capacitor, a first current source, a switch, a second capacitor, and a driver circuit. The clamp voltage generating circuit includes a third capacitor, a fourth capacitor, a first resistor, and a second current source.

### CROSS REFERENCE TO RELATED APPLICATIONS

This application claims priority benefit of Japanese Patent Application No. JP 2022-160419 filed in the Japan Patent Office on Oct. 4, 2022. Each of the above-referenced applications is hereby incorporated herein by reference in its entirety.

### BACKGROUND

The present disclosure relates to a step-down direct current/direct current (DC/DC) converter.

A step-down (buck) DC/DC converter is used in order to generate a voltage lower than an input voltage.

A controller circuit of the step-down DC/DC converter executes feedback control of a switching transistor of the step-down DC/DC converter to cause a feedback signal indicating an electrical state, specifically, an output voltage or an output current, of the step-down DC/DC converter to come close to a target state.

A semiconductor chip (die) on which the controller circuit is integrated is housed in a semiconductor package. In the semiconductor package, an electrode pad of the semiconductor chip is connected to a pin of the semiconductor package through a bonding wire.

An example of the related art is disclosed in Japanese Patent No. 7102307.

### BRIEF DESCRIPTION OF THE DRAWINGS

FIG. 1 is a circuit diagram of a step-down DC/DC converter according to an embodiment;

FIG. 2 is a level diagram of the input voltage range of a pulse width modulation (PWM) comparator and a ramp voltage;

FIG. 3 is a circuit diagram of a ramp voltage generating circuit and a clamp voltage generating circuit according to the embodiment;

FIG. 4 is a diagram for explaining operation of the ramp voltage generating circuit and the clamp voltage generating circuit in FIG. 3;

FIG. 5 is a circuit diagram illustrating a configuration example of a first current source;

FIG. 6 is a circuit diagram of a clamp voltage generating circuit according to a modification example 1; and

FIG. 7 is a block diagram of a power supply system including step-down converters.

### DETAILED DESCRIPTION

### Outline of Embodiments

The outline of several illustrative embodiments of the present disclosure will be described. This outline explains several concepts of one or a plurality of embodiments in a simplified manner for the purpose of achieving basic understanding of the embodiments as an introduction of detailed explanation to be described later, but does not limit the extent of the technology or the disclosure. This outline is not a comprehensive outline of all embodiments that are conceivable and intends to neither identify important factors of all embodiments nor delimit the range of some or all of the embodiments. For convenience, “one embodiment” is used to refer to one embodiment (one working example or one modification example) or a plurality of embodiments (working examples or modification examples) disclosed in the present specification, in some cases.

A controller circuit of a step-down DC/DC converter according to one embodiment includes a ramp voltage generating circuit that generates a periodic ramp voltage, a clamp voltage generating circuit that generates a clamp voltage, an error amplifier that generates an error signal that depends on an error between an electrical state of the step-down DC/DC converter and a target state of the electrical state, a clamp circuit that clamps the error signal by using the clamp voltage, and a pulse width modulation comparator that compares the error signal resulting from the clamping by the clamp circuit with the ramp voltage. The ramp voltage generating circuit includes a first capacitor having a first end that is grounded and a second end, a first current source that supplies, to the second end of the first capacitor, a first current that depends on a supply voltage supplied to the controller circuit, a switch connected to the first capacitor in parallel, a second capacitor having a first end connected to the second end of the first capacitor and a second end, and a driver circuit that turns on the switch in response to a reset signal and applies a reference voltage having a predetermined voltage level to the second end of the second capacitor. The clamp voltage generating circuit includes a third capacitor having a first end that is grounded and a second end, a fourth capacitor having a first end connected to the second end of the third capacitor and a second end that receives the reference voltage, a first resistor having a first end that receives a voltage of the second end of the third capacitor and a second end, and a second current source that supplies a second current to the second end of the first resistor. The clamp voltage depends on a voltage generated at the second end of the first resistor.

The error voltage rises when a feedback path is interrupted. However, the error voltage is clamped so as not to exceed the clamp voltage, by the clamp circuit. Owing to this, the DC/DC converter operates in a range in which the duty cycle does not exceed the upper limit that depends on the clamp voltage, and the overvoltage of the output can be suppressed. Here, when the supply voltage supplied from the external to the controller circuit varies, the variation range of the ramp voltage changes. The clamp voltage generating circuit can change the voltage level of the clamp voltage in such a manner as to follow the change in the variation range of the ramp voltage. This can cause the upper limit of the duty cycle to follow the variation in the supply voltage.

In one embodiment, the second current generated by the second current source may be a constant current that does not depend on the supply voltage.

In one embodiment, the second current generated by the second current source may depend on the supply voltage. In this case, the upper limit of the duty cycle can be kept constant irrespective of variation in the supply voltage.

In one embodiment, the supply voltage may be an input voltage of the step-down DC/DC converter.

In one embodiment, the driver circuit may include a buffer that receives the reference voltage at a power supply line and whose output is connected to the second end of the second capacitor and a control node of the switch.

In one embodiment, the clamp voltage generating circuit may further include a first buffer that receives the voltage of the second end of the third capacitor and outputs the voltage of the second end of the third capacitor to the first end of the first resistor.

In one embodiment, the clamp voltage generating circuit may further include a second buffer that receives the voltage generated at the second end of the first resistor and outputs the clamp voltage.

In one embodiment, the first current source and the second current source may have the same configuration.

In one embodiment, the first current source may include a resistor divider circuit that divides the supply voltage, a second resistor having a first end that is grounded, a transistor having a first end connected to a second end of the second resistor, an operational amplifier that receives an output voltage of the resistor divider circuit at a non-inverting input terminal, whose inverting input terminal is connected to the second end of the second resistor, and whose output is connected to a control terminal of the transistor, and a current mirror circuit that folds back a current that flows in the transistor.

In one embodiment, the step-down DC/DC converter may be a secondary DC/DC converter that steps down an output voltage of a primary DC/DC converter at a previous stage.

In one embodiment, the controller circuit is integrated on the same chip as a controller circuit of the primary DC/DC converter, and the controller circuit of the primary DC/DC converter does not include the clamp circuit.

In one embodiment, the controller circuit may be monolithically integrated on one semiconductor substrate. The “monolithically integrated” includes the case in which all of constituent elements of the circuit are formed on the semiconductor substrate and the case in which major constituent elements of the circuit are monolithically integrated, and some resistors, capacitors, and other constituent elements may be disposed outside the semiconductor substrate for adjustment of the circuit constant. By integrating the circuit on one chip, the circuit area can be reduced, and characteristics of circuit elements can be kept uniform.

An in-vehicle power supply system according to one embodiment may include any of the above-described controller circuits.

### Embodiments

Preferred embodiments will be described below with reference to the drawings. The same or equivalent constituent element, component, and processing illustrated in the drawings are given the same numeral or symbol, and overlapping description is omitted as appropriate. Further, the embodiments do not limit the disclosure and the technology but exemplification, and all characteristics described in the embodiments and combinations thereof are not necessarily essential matters of the disclosure and the technology.

In the present specification, “the state in which a component A is connected to a component B” includes, besides the case in which the component A and the component B are physically and directly connected to each other, also the case in which the component A and the component B are indirectly connected to each other with the interposition of another component that does not have a substantial influence on the electrical connection state of the component A and the component B or does not impair functions and effects provided by the coupling of the component A and the component B.

Similarly, “the state in which a component C is connected (disposed) to and between the component A and the component B” includes, besides the case in which the component A and the component C or the component B and the component C are directly connected to each other, also the case in which the component A and the component C or the component B and the component C are indirectly connected to each other with the interposition of another component that does not have a substantial influence on the electrical connection state of the component A and the component C or the component B and the component C or does not impair functions and effects provided by the coupling of the component A and the component C or the component B and the component C.

Further, in the present specification, a symbol given to an electrical signal such as a voltage signal or current signal or a circuit element such as a resistor, capacitor, or inductor represents each voltage value, current value, or circuit constant (resistance value, capacitance value, inductance) according to need.

The ordinate axis and the abscissa axis of a waveform diagram or time chart to which a reference is made in the present specification are appropriately enlarged or contracted for facilitation of understanding, and the waveforms illustrated are also simplified or are exaggerated or emphasized for facilitation of understanding.

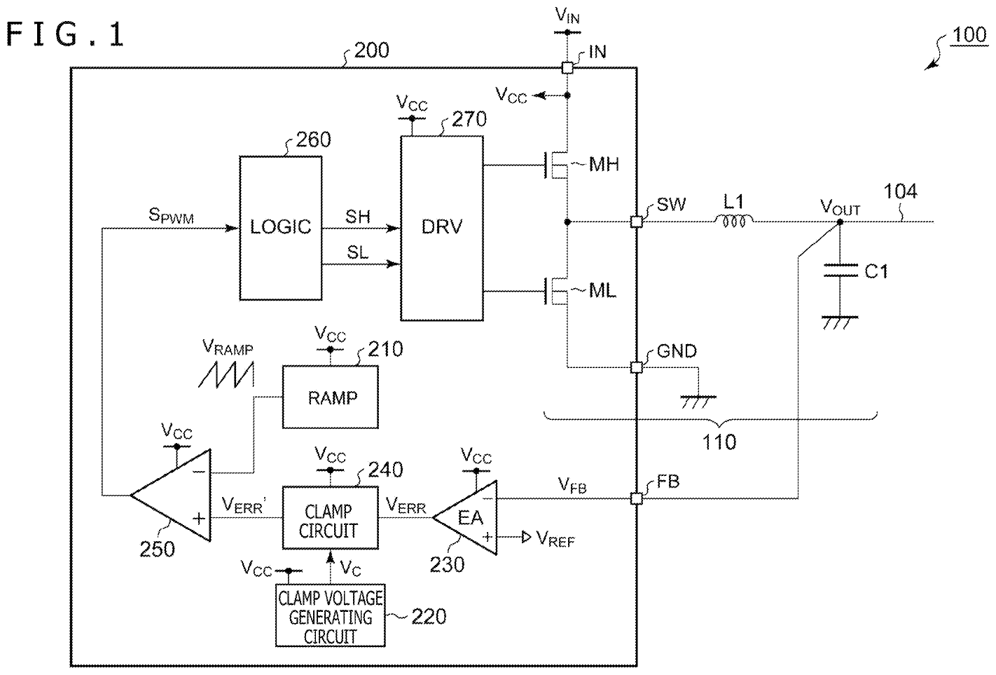

FIG. 1 is a circuit diagram of a step-down DC/DC converter (hereinafter, referred to as a step-down converter) 100 according to an embodiment. The step-down converter 100 steps down an input voltage Vin supplied to an input line 102 and generates, on an output line 104, an output voltage V_{OUT} resulting from the stepping-down.

The step-down converter 100 includes a main circuit 110 and a controller integrated circuit (IC) 200. The controller IC 200 is an application specific integrated circuit (ASIC) integrated on one semiconductor substrate.

The main circuit 110 includes a high-side transistor MH, a low-side transistor ML, an inductor L1, and an output capacitor C1. The high-side transistor MH and the low-side transistor ML are connected in series between the input line 102 and a ground. The inductor L1 is connected to and between a connecting node (referred to as a switching node or a switching pin) SW of the high-side transistor MH and the low-side transistor ML and the output line 104. The output capacitor C1 is connected to and between the output line 104 and a ground. The high-side transistor MH and the low-side transistor ML may be integrated in the controller IC 200 or may be external discrete parts.

The controller IC 200 includes an input pin VIN, the switching pin SW, a ground pin GND, and a feedback pin FB. The direct-current input voltage Vin is supplied from the external to the input pin VIN. The input voltage Vin is an input voltage of the DC/DC converter and is a supply voltage Vcc of the controller IC 200, and is supplied to an analog circuit block inside the controller IC 200. The feedback pin FB is connected to the output line 104.

The high-side transistor MH is connected to and between the input pin VIN and the switching pin SW. The low-side transistor ML is connected to and between the switching pin SW and the ground pin GND.

The controller IC 200 includes a ramp voltage generating circuit 210, a clamp voltage generating circuit 220, an error amplifier 230, a clamp circuit 240, a PWM comparator 250, a logic circuit 260, and a driver circuit 270 in addition to the high-side transistor MH and the low-side transistor ML.

The ramp voltage generating circuit 210 generates a periodic ramp voltage V_{RAMP}. The clamp voltage generating circuit 220 generates a clamp voltage Vc.

A feedback signal V_{FB} indicating an electrical state of the step-down converter 100 is input to the feedback pin FB. The electrical state of the step-down converter 100 is the output voltage V_{OUT} of the step-down converter 100, for example.

The error amplifier 230 generates an error signal V_{ERR} that depends on the error between the electrical state of the step-down converter 100 (that is, the output voltage V_{OUT}) and a target state thereof (the reference voltage V_{REF}).

The clamp circuit 240 clamps the error signal V_{ERR} by using the clamp voltage Vc.

The PWM comparator 250 compares an error signal V_{ERR}′ resulting from the clamping by the clamp circuit 240 with the ramp voltage V_{RAMP} and generates a PWM signal S_{PWM} that depends on the comparison result. The logic circuit 260 generates a high-side pulse SH to control switching-on/off of the high-side transistor MH and a low-side pulse SL to control switching-on/off of the low-side transistor ML, according to the PWM signal S_{PWM}. The driver circuit 270 drives the high-side transistor MH in response to the high-side pulse SH and drives the low-side transistor ML in response to the low-side pulse SL.

The above is the overall configuration of the step-down converter 100.

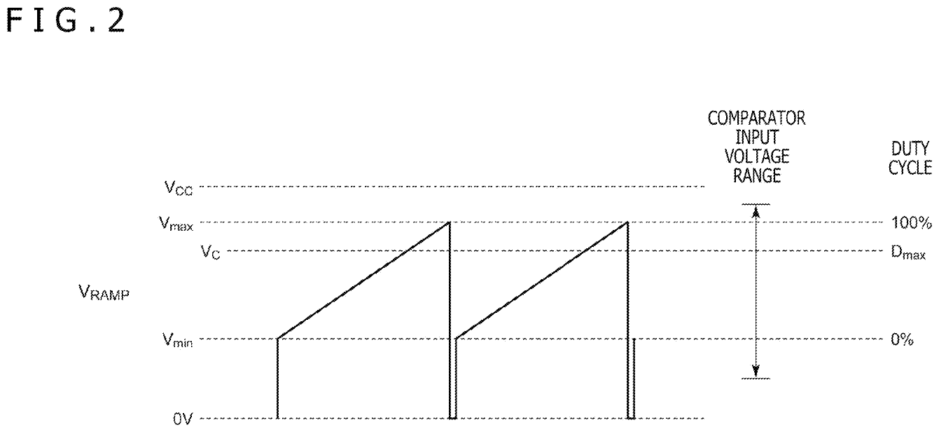

FIG. 2 is a level diagram of the input voltage range of the PWM comparator 250 and the ramp voltage V_{RAMP}.

The PWM comparator 250 is capable of accurate voltage comparison only in a predetermined input voltage range. Thus, when the duty cycle is desired to be changed in a wide range, a maximum voltage Vmax and a minimum voltage Vmin of the ramp voltage V_{RAMP} need to be included in the input voltage range of the PWM comparator 250. The maximum voltage Vmax of the ramp voltage V_{RAMP} is equivalent to a 100% duty cycle, and the minimum voltage Vmin is equivalent to a 0% duty cycle.

The relation between the clamp voltage Vc in the clamp circuit 240 and an upper limit value (maximum duty cycle) Dmax of the duty cycle is represented by the following expression.

Dmax=(Vmax−Vc)/(Vmax−Vmin) (1)

The supply voltage Vcc (=Vin) is supplied to the ramp voltage generating circuit 210. When the supply voltage Vcc changes, the amplitude of the ramp voltage V_{RAMP}, that is, the maximum voltage Vmax, changes. Thus, if the clamp voltage Vc is made constant, the maximum duty cycle Dmax changes when the supply voltage Vcc varies. In the following, description will be made with regard to the configurations of the ramp voltage generating circuit 210 and the clamp voltage generating circuit 220 that can suppress change in the maximum duty cycle Dmax when the supply voltage Vcc changes.

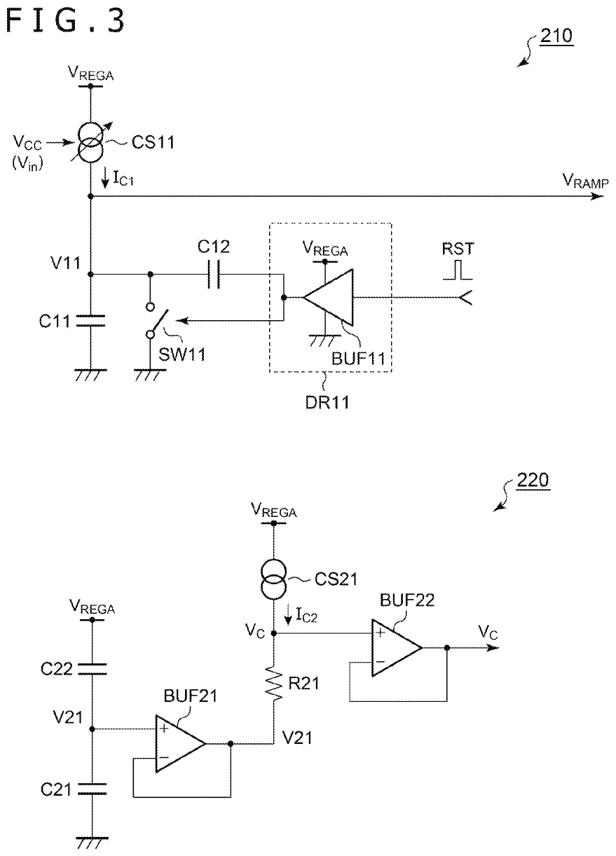

FIG. 3 is a circuit diagram of the ramp voltage generating circuit 210 and the clamp voltage generating circuit 220 according to the embodiment.

The ramp voltage generating circuit 210 includes a first capacitor C11, a first current source CS11, a switch SW11, a second capacitor C12, and a driver circuit DR11. A first end of the first capacitor C11 is grounded. The first current source CS11 supplies, to a second end of the first capacitor C11, a first current Ic1 that depends on the supply voltage Vcc supplied to the controller IC 200. Specifically, the first current Ic1 is proportional to the supply voltage Vcc.

The switch SW11 is connected to the first capacitor C11 in parallel. For example, the switch SW11 can be configured by an N-channel metal oxide semiconductor (NMOS) transistor. A first end of the second capacitor C12 is connected to the second end of the first capacitor C11.

The driver circuit DR11 turns on the switch SW11 in response to assertion of a reset signal RST and applies a reference voltage V_{REGA} having a predetermined voltage level to a second end of the second capacitor C12. The reset signal RST is a periodic signal generated by an oscillator that is not illustrated, and the reset signal RST defines the switching frequency of the step-down converter 100. For example, the driver circuit DR11 includes a buffer BUF11 that receives the reference voltage V_{REGA} at a power supply line and whose output is connected to the second end of the second capacitor C12 and a control node (gate) of the switch SW11.

The reference voltage V_{REGA} can be set to 3.3 V, for example, and be generated by a combination of a linear regulator and a bandgap reference circuit that are not illustrated. When the reference voltage V_{REGA} is applied to the second end of the second capacitor C12, a voltage V11 is initialized to the minimum voltage Vmin represented by expression (2).

Vmin=C12×(C11+C12)×V_{REGA} (2)

The above is the configuration of the ramp voltage generating circuit 210. Subsequently, the configuration of the clamp voltage generating circuit 220 will be described.

The clamp voltage generating circuit 220 includes a third capacitor C21, a fourth capacitor C22, a second current source CS21, a first buffer BUF21, and a second buffer BUF22.

A first end of the third capacitor C21 is grounded. A first end of the fourth capacitor C22 is connected to a second end of the third capacitor C21. The reference voltage V_{REGA} is applied to a second end of the fourth capacitor C22. A voltage V21 obtained by dividing the reference voltage V_{REGA} represented by expression (3) is generated at a connecting node of the third capacitor C21 and the fourth capacitor C22. C11:C12=C21:C22 holds, and the voltage V21 is equal to the minimum value Vmin.

V21=C22×(C21+C22)×V_{REGA}=Vmin (3)

The voltage V21 of the second end of the third capacitor C21 is applied to a first end of a first resistor R21 through the first buffer BUF21.

The second current source CS21 supplies a second current Ic2 to a second end of the first resistor R21. A voltage drop R21×Ic2 occurs across the first resistor R21. The voltage Vc generated at the second end of the first resistor R21 is represented by expression (4).

Vc=Vmin+R21×Ic2 (4)

The second buffer BUF22 outputs the voltage Vc as the clamp voltage.

The first buffer BUF21 and the second buffer BUF22 may be omitted.

The above is the configurations of the ramp voltage generating circuit 210 and the clamp voltage generating circuit 220. Subsequently, operation thereof will be described.

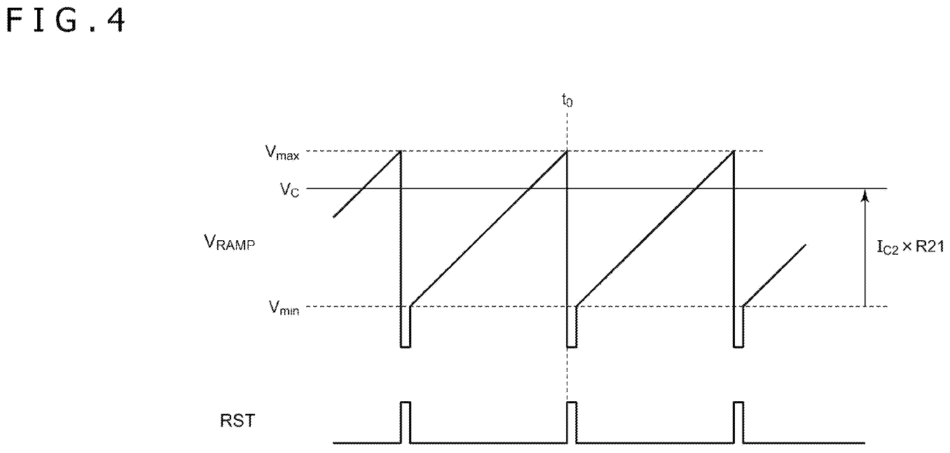

FIG. 4 is a diagram for explaining operation of the ramp voltage generating circuit 210 and the clamp voltage generating circuit 220 in FIG. 3.

At a clock time to, the reset signal RST supplied from the oscillator to the ramp voltage generating circuit 210 is asserted. When the reset signal RST is asserted, the switch SW11 is turned on, and the ramp voltage V_{RAMP} becomes 0 V. Then, when the driver circuit DR11 applies the reference voltage V_{REGA} to the capacitor C12, the ramp voltage V_{RAMP} is reset to the minimum voltage Vmin represented by the above-described expression (3).

Then, the ramp voltage V_{RAMP} rises again from the minimum voltage Vmin. When the reset signal RST is asserted at a clock time t₁, the ramp voltage V_{RAMP} is reset to the minimum voltage Vmin.

In the clamp voltage generating circuit 220, the clamp voltage Vc is generated by executing level shift of the voltage V21 obtained by dividing the reference voltage V_{REGA} by the capacitors C21 and C22, the reference voltage V_{REGA} corresponding to the voltage drop across the first resistor R21. As described above, the voltage V21 is equal to the minimum voltage Vmin of the ramp voltage V_{RAMP}. That is, the clamp voltage Vc is generated on the basis of the minimum voltage Vmin and becomes a constant voltage that does not depend on the supply voltage Vcc.

The above is operation of the ramp voltage generating circuit 210 and the clamp voltage generating circuit 220. In the controller IC 200 including the ramp voltage generating circuit 210 and the clamp voltage generating circuit 220, the clamp voltage Vc is generated based on the minimum voltage Vmin that does not depend on the supply voltage Vcc, even when the maximum voltage Vmax varies in association with variation in the supply voltage Vcc (input voltage Vin). Therefore, even when the supply voltage Vcc varies, it is ensured that the clamp voltage Vc is included in the range between the minimum voltage Vmin and the maximum voltage Vmax.

Suppose that an abnormality of interruption of the feedback path on which the feedback signal is transmitted has occurred in the controller IC 200. Such an abnormality possibly occurs due to detachment of a bonding wire or detachment between a pin of a semiconductor package and solder of a printed board, for example.

In this case, the voltage V_{FB} of an inverting input terminal of the error amplifier 230 lowers to 0 V. At this time, the error voltage V_{ERR} that is the output of the error amplifier 230 becomes high. However, the error voltage V_{ERR} is clamped so as not to exceed the clamp voltage Vc, by the clamp circuit 240, and the error V_{ERR} resulting from the clamping=Vc is supplied to the PWM comparator 250. Therefore, the PWM signal S_{PWM} is fixed at the maximum duty cycle that depends on the clamp voltage Vc and does not become higher than it. This can suppress the occurrence of the situation in which the output voltage V_{OUT} becomes an overvoltage state.

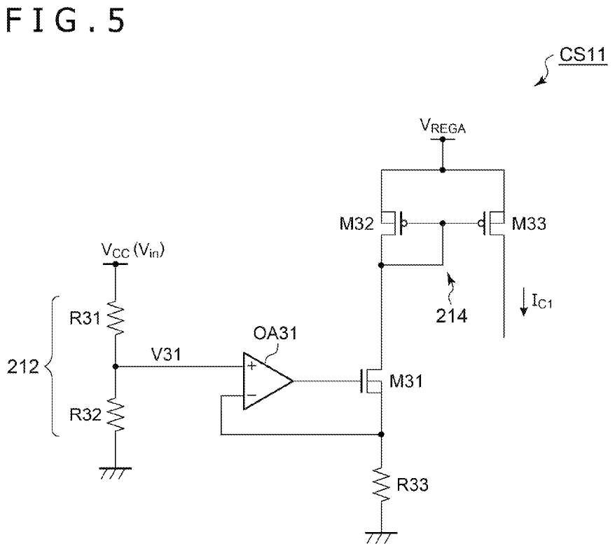

FIG. 5 is a circuit diagram illustrating a configuration example of the first current source CS11. The first current source CS11 includes a resistor divider circuit 212, a second resistor R33, a transistor M31, and a current mirror circuit 214. The resistor divider circuit 212 includes resistors R31 and R32 and divides the supply voltage Vcc.

A first end of the second resistor R33 is grounded. The transistor M31 is an NMOS transistor, and a first end (source) thereof is connected to the second resistor R33. An operational amplifier OA31 receives the output voltage V31 of the resistor divider circuit 212 at a non-inverting input terminal and has an inverting input terminal connected to the source of the transistor M31. The current mirror circuit 214 includes P-channel MOS (PMOS) transistors M32 and M33 and folds back a current that flows in the transistor M31, to output the folded-back current as the first current Ic1.

The first current Ic1 is a current proportional to the supply voltage Vcc.

The second current source CS21 can be configured in a manner similar to that of the first current source CS11 of FIG. 5. However, because the second current Ic2 is a constant current that does not depend on the supply voltage Vcc, the reference voltage V_{REF} having a predetermined voltage level is input to the resistor divider circuit 212, instead of the supply voltage Vcc.

### Modification Example 1

In the embodiment, the second current Ic2 is a constant current. However, the configuration is not limited thereto. In a modification example 1, a current proportional to the supply voltage Vcc can be used as the second current Ic2.

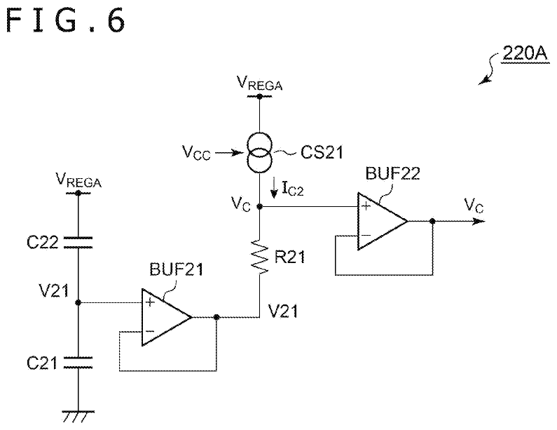

FIG. 6 is a circuit diagram of a clamp voltage generating circuit 220A according to the modification example 1. The second current source CS21 generates the second current Ic2 proportional to the supply voltage Vcc, similarly to the first current source CS11 in FIG. 3. The other configuration is the same as that of the clamp voltage generating circuit 220 in FIG. 3.

The clamp voltage Vc is represented by expression (4), as described above.

Vc=Vmin+R21×Ic2 (4)

In the embodiment, the second current Ic2 is a constant current, and therefore, the clamp voltage Vc takes a constant level irrespective of the supply voltage Vcc. In contrast, in the modification example 1, the second current Ic2 changes according to the supply voltage Vcc. Owing to this, the dependence of the maximum duty cycle Dmax on the supply voltage Vcc can be made small.

### Modification Example 2

In the embodiment, the case in which Vcc=Vin holds has been described. However, the configuration is not limited thereto. The supply voltage Vcc may be supplied to the controller IC 200 separately from the input voltage Vin.

### (Use Purpose)

Subsequently, a use purpose of the step-down converter 100 will be described.

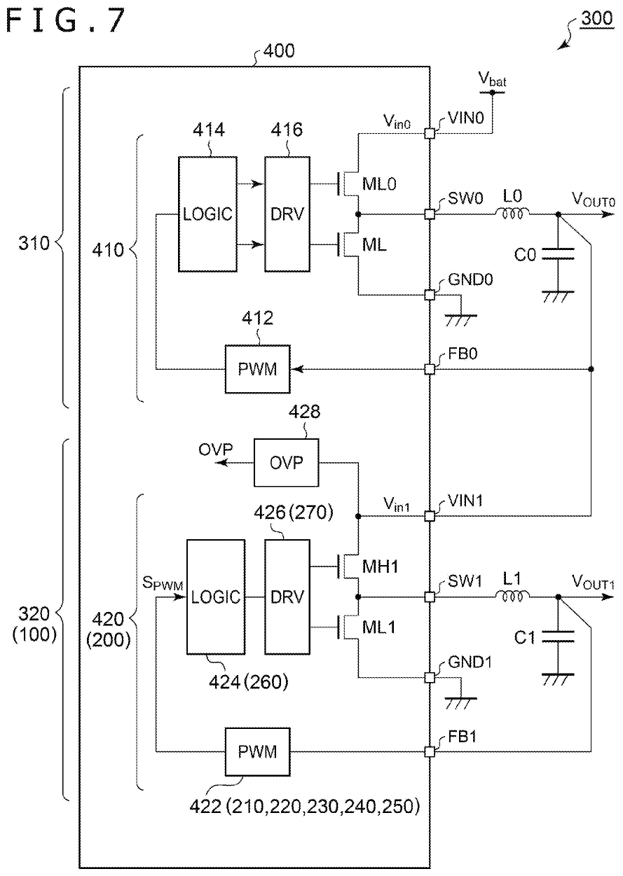

FIG. 7 is a block diagram of a power supply system 300 including the step-down converter 100. For example, the power supply system 300 is mounted in an automobile. The power supply system 300 includes a primary converter 310 and a secondary converter 320.

The primary converter 310 steps down a battery voltage Vbat to generate an output voltage Vout0.

The secondary converter 320 receives the output voltage Vout0 as an input voltage Vin1 and steps down it to generate an output voltage Vout1. The step-down converter 100 according to the embodiment corresponds to the secondary converter 320.

A power supply management circuit 400 is a functional IC in which a controller circuit 410 of the primary converter 310 and a part of a controller circuit 420 of the secondary converter 320 are integrated. The controller circuit 410 includes a pulse width modulator 412, a logic circuit 414, and a driver 416.

The controller circuit 420 corresponds to the above-described controller IC 200 and is configured to be capable of suppressing an overvoltage attributed to solder detachment of a feedback pin FB1, for example. The controller circuit 420 includes a pulse width modulator 422, a logic circuit 424, and a driver circuit 426. The pulse width modulator 422 includes the ramp voltage generating circuit 210, the clamp voltage generating circuit 220, the error amplifier 230, the clamp circuit 240, and the PWM comparator 250 in FIG. 1.

The logic circuit 424 corresponds to the logic circuit 260 in FIG. 1, and the driver circuit 426 corresponds to the driver circuit 270 in FIG. 1.

The controller circuit 420 of the secondary converter 320 includes an overvoltage protection circuit 428. The overvoltage protection circuit 428 monitors the input voltage Vin1 of the controller circuit 420 and asserts an overvoltage protection signal OVP that becomes a trigger for overvoltage protection, when the input voltage Vin1 exceeds a predetermined threshold voltage Vovp. The power supply management circuit 400 executes a predetermined protection sequence in response to the assertion of the OVP signal.

The clamp function of the maximum duty cycle described in the embodiment is not implemented in the controller circuit 410 of the primary converter 310. This is because, although the output voltage Vout0 rises when an abnormality has occurred in a feedback path of the primary converter 310, the rise in the output voltage Vout0 can be detected by the overvoltage protection circuit 428 and protection can be properly implemented.

It is understood by those skilled in the art that the embodiments are exemplification and various modification examples exist in combinations of the respective constituent elements and the respective processing processes of them and that such modification examples are also included in the present disclosure and can configure the scope of the present technology.

### (Additional Notes)

The following techniques are disclosed in the present disclosure.

### (Item 1)

A controller circuit of a step-down DC/DC converter, the controller circuit including:

a ramp voltage generating circuit that generates a periodic ramp voltage;

a clamp voltage generating circuit that generates a clamp voltage;

an error amplifier that generates an error signal that depends on an error between an electrical state of the step-down DC/DC converter and a target state of the electrical state;

a clamp circuit that clamps the error signal by using the clamp voltage; and

a pulse width modulation comparator that compares the error signal resulting from the clamping by the clamp circuit with the ramp voltage, in which

the ramp voltage generating circuit includes
a first capacitor having a first end that is grounded and a second end,
a first current source that supplies, to the second end of the first capacitor, a first current that depends on a supply voltage supplied to the controller circuit,
a switch connected to the first capacitor in parallel,
a second capacitor having a first end connected to the second end of the first capacitor and a second end, and
a driver circuit that turns on the switch in response to a reset signal and applies a reference voltage having a predetermined voltage level to the second end of the second capacitor,

the clamp voltage generating circuit includes
a third capacitor having a first end that is grounded and a second end,
a fourth capacitor having a first end connected to the second end of the third capacitor and a second end that receives the reference voltage,
a first resistor having a first end that receives a voltage of the second end of the third capacitor and a second end, and
a second current source that supplies a second current to the second end of the first resistor, and the clamp voltage depends on a voltage generated at the second end of the first resistor.

### (Item 2)

The controller circuit according to Item 1, in which

the second current is a constant current.

### (Item 3)

The controller circuit according to Item 1, in which

the second current depends on the supply voltage.

### (Item 4)

The controller circuit according to any one of Items 1 to 3, in which

the supply voltage is an input voltage of the step-down DC/DC converter.

### (Item 5)

The controller circuit according to any one of Items 1 to 4, in which

the driver circuit includes a buffer that receives the reference voltage at a power supply line and whose output is connected to the second end of the second capacitor and a control node of the switch.

### (Item 6)

The controller circuit according to any one of Items 1 to 5, in which

the clamp voltage generating circuit further includes a first buffer that receives the voltage of the second end of the third capacitor and outputs the voltage of the second end of the third capacitor to the first end of the first resistor.

### (Item 7)

The controller circuit according to any one of Items 1 to 6, in which

the clamp voltage generating circuit further includes a second buffer that receives the voltage generated at the second end of the first resistor and outputs the clamp voltage.

### (Item 8)

The controller circuit according to any one of Items 1 to 7, in which

the first current source and the second current source have the same configuration.

### (Item 9)

The controller circuit according to any one of Items 1 to 8, in which

the first current source includes
a resistor divider circuit that divides the supply voltage,
a second resistor having a first end that is grounded,
a transistor having a first end connected to a second end of the second resistor,
an operational amplifier that receives an output voltage of the resistor divider circuit at a non-inverting input terminal, whose inverting input terminal is connected to the second end of the second resistor, and whose output is connected to a control terminal of the transistor, and
a current mirror circuit that folds back a current that flows in the transistor.

### (Item 10)

The controller circuit according to any one of Items 1 to 9, in which

the step-down DC/DC converter is a secondary DC/DC converter that steps down an output voltage of a primary DC/DC converter at a previous stage.

### (Item 11)

The controller circuit according to Item 10, in which

the controller circuit is integrated on the same chip as a controller circuit of the primary DC/DC converter, and

the controller circuit of the primary DC/DC converter does not include the clamp circuit.

### (Item 12)

The controller circuit according to any one of Items 1 to 11, in which

the controller circuit is monolithically integrated on one semiconductor substrate.

### (Item 13)

An in-vehicle power supply system including:

the controller circuit according to any one of Items 1 to 12.

According to an embodiment of the present disclosure, the overvoltage of the output can be suppressed.

What is claimed is:

1. A controller circuit of a step-down direct current/direct current converter, the controller circuit comprising:
a ramp voltage generating circuit that generates a periodic ramp voltage;
a clamp voltage generating circuit that generates a clamp voltage;
an error amplifier that generates an error signal that depends on an error between an electrical state of the step-down direct current/direct current converter and a target state of the electrical state;
a clamp circuit that clamps the error signal by using the clamp voltage; and
a pulse width modulation comparator that compares the error signal resulting from the clamping by the clamp circuit with the ramp voltage, wherein
the ramp voltage generating circuit includes
a first capacitor having a first end that is grounded and a second end,
a first current source that supplies, to the second end of the first capacitor, a first current that depends on a supply voltage supplied to the controller circuit,
a switch connected to the first capacitor in parallel,
a second capacitor having a first end connected to the second end of the first capacitor and a second end, and
a driver circuit that turns on the switch in response to a reset signal and applies a reference voltage having a predetermined voltage level to the second end of the second capacitor,
the clamp voltage generating circuit includes
a third capacitor having a first end that is grounded and a second end,
a fourth capacitor having a first end connected to the second end of the third capacitor and a second end that receives the reference voltage,
a first resistor having a first end that receives a voltage of the second end of the third capacitor and a second end, and
a second current source that supplies a second current to the second end of the first resistor, and
the clamp voltage depends on a voltage generated at the second end of the first resistor.

2. The controller circuit according to claim 1, wherein
the second current is a constant current.

3. The controller circuit according to claim 1, wherein
the second current depends on the supply voltage.

4. The controller circuit according to claim 1, wherein
the supply voltage is an input voltage of the step-down direct current/direct current converter.

5. The controller circuit according to claim 1, wherein
the driver circuit includes a buffer that receives the reference voltage at a power supply line and whose output is connected to the second end of the second capacitor and a control node of the switch.

6. The controller circuit according to claim 1, wherein
the clamp voltage generating circuit further includes a first buffer that receives the voltage of the second end of the third capacitor and outputs the voltage of the second end of the third capacitor to the first end of the first resistor.

7. The controller circuit according to claim 1, wherein
the clamp voltage generating circuit further includes a second buffer that receives the voltage generated at the second end of the first resistor and outputs the clamp voltage.

8. The controller circuit according to claim 1, wherein
the first current source and the second current source have a same configuration.

9. The controller circuit according to claim 1, wherein
the first current source includes
a resistor divider circuit that divides the supply voltage,
a second resistor having a first end that is grounded,
a transistor having a first end connected to a second end of the second resistor,
an operational amplifier that receives an output voltage of the resistor divider circuit at a non-inverting input terminal, whose inverting input terminal is connected to the second end of the second resistor, and whose output is connected to a control terminal of the transistor, and
a current mirror circuit that folds back a current that flows in the transistor.

10. The controller circuit according to claim 1, wherein
the step-down direct current/direct current converter is a secondary direct current/direct current converter that steps down an output voltage of a primary direct current/direct current converter at a previous stage.

11. The controller circuit according to claim 10, wherein
the controller circuit is integrated on a same chip as a controller circuit of the primary direct current/direct current converter, and
the controller circuit of the primary direct current/direct current converter does not include the clamp circuit.

12. The controller circuit according to claim 1, wherein
the controller circuit is monolithically integrated on one semiconductor substrate.

13. An in-vehicle power supply system comprising:
the controller circuit according to claim 1.
